(19) United States
(12) Patent Application Publication
(10) Pub. No.: US 2024/0334588 A1
(43) Pub. Date: Oct. 3, 2024

(54) ELECTRONIC DEVICE COMPRISING PLURALITY OF PRINTED CIRCUIT BOARDS

(71) Applicant: Samsung Electronics Co., Ltd., Suwon-si (KR)

(72) Inventors: Jichul KIM, Suwon-si (KR); Jaeheung YE, Suwon-si (KR); Kyuhwan LEE, Suwon-si (KR); Kwangho JUNG, Suwon-si (KR)

(21) Appl. No.: 18/739,889

(22) Filed: Jun. 11, 2024

Related U.S. Application Data
(63) Continuation of application No. PCT/KR2023/010060, filed on Jul. 13, 2023.

(30) Foreign Application Priority Data
Jul. 13, 2022 (KR) 10-2022-0086498
Sep. 30, 2022 (KR) 10-2022-0125828

(51) Int. Cl. H05K 1/02; H05K 1/14; H05K 1/18; H05K 7/20

(52) U.S. Cl. CPC H05K 1/0203; H05K 1/145; H05K 1/181; H05K 7/20409; H05K 2201/10159; H05K 2201/10318; H05K 2201/10568

(57) ABSTRACT

An electronic device according to an embodiment of the disclosure may include: a first circuit board; a second circuit board with a first surface facing a first direction, and a second surface facing a second direction opposite to the first direction and facing the first circuit board; a first electronic component disposed between the first circuit board and the second surface of the second circuit board, and disposed in a first area of the second circuit board; a second electronic component disposed in a second area of the second circuit board; a heat dissipation device comprising a thermally conductive material disposed on the first surface of the second circuit board; a first heat transfer member comprising a thermally conductive material configured to transfer heat from the first electronic component to the heat dissipation device; and a second heat transfer member comprising a thermally conductive material configured to transfer heat from the second electronic component to the first circuit board.

### CROSS-REFERENCE TO RELATED APPLICATIONS

This application is a continuation of International Application No. PCT/KR2023/010060 designating the United States, filed on Jul. 13, 2023, in the Korean Intellectual Property Receiving Office and claiming priority to Korean Patent Application Nos. 10-2022-0086498, filed on Jul. 13, 2022, and 10-2022-0125828, filed on Sep. 30, 2022, in the Korean Intellectual Property Office, the disclosures of all of which are incorporated by reference herein in their entireties.

### BACKGROUND

### Field

The disclosure relates to an electronic device, and to an electronic device including a plurality of printed circuit boards.

### Description of Related Art

Due to recent remarkable developments in information communication and semiconductor technologies, the dissemination and utilization of various electronic devices have rapidly increased. Particularly, there have been recent developments in electronic devices that allow for communication while being carried. In addition, electronic devices may output stored information in the form of sound or images. With the increasing integration of electronic devices and the common use of ultra-high-speed and large-volume wireless communication, various functions have recently come to be provided in a single electronic device, such as a mobile communication terminal. For example, various functions such as an entertainment function such as gaming, a multimedia function such as music/video playback, a communication and security function for mobile banking, and a function such as a schedule management or electronic wallet, as well as a communication function have been integrated into a single electronic device. These electronic devices have become increasingly more compact, making it convenient for users to carry them.

In order to implement various functions on a single electronic device, an electronic device may be equipped with components (e.g., a processor) capable of performing high-performance calculations and components (e.g., a memory) for storing various data. In mounting these components (e.g., processor and/or memory) in an electronic device, ongoing research has been conducted to find ways to efficiently dissipate high-temperature heat generated from the components as well as increase the efficiency of the mounting space.

Various components (for example, an application processor, a communication processor, or a connector) are typically mounted on a printed circuit board in an electronic device using a surface mounted device (SMD) process. In mounting various components in an electronic device, according to various embodiments, these components may be arranged on a single circuit board and electrically connected through signal lines disposed on the circuit board. Alternatively, a stacked board structure (hereinafter referred to as “stacked PCB structure”) in which two or more boards are stacked, may be used to effectively utilize limited arrangement space. In this case, some component(s) may be mounted in a system-on-chip (SoC) form or modularized and mounted in a package-on-package (POP) form in which multiple components are stacked in a height direction.

When components are arranged on a single circuit board and electrically connected through signal lines disposed on the circuit board, the design of the circuit board for signal connections between the components may become complicated, and the overall size of package may increase. In addition, when multiple components are arranged in a stacked POP form in the height direction, for example, heat generated from a component disposed at the bottom may be blocked by a component disposed at the top, making it difficult to dissipate heat and resulting in reduced heat dissipation efficiency.

However, the problems addressed in the disclosure are not limited to the above-mentioned problems, and may be variously expanded without departing from the spirit and scope of the disclosure.

### SUMMARY

According to an example embodiment of the disclosure, an electronic device may include: a first circuit board; a second circuit board including a first surface facing a first direction, and a second surface facing a second direction opposite to the first direction and facing the first circuit board. The electronic device may include a first electronic component disposed between the first circuit board and the second surface of the second circuit board, and disposed in a first area of the second circuit board; and a second electronic component disposed between the first circuit board and the second surface of the second circuit board, and disposed in a second area of the second circuit board. The electronic device may include a heat dissipation device comprising a heat dissipating material disposed on a first surface of the second circuit board. The electronic device may include a first heat transfer member comprising a thermally conductive material disposed in an opening formed in the first area of the second circuit board, between the second surface of the second circuit board and the first circuit board and configured to transfer heat from the first electronic component to the heat dissipation device; and a second heat transfer member comprising a thermally conductive material disposed between the second electronic component and the first circuit board and configured to transfer heat from the second electronic component to the first circuit board.

According to an example embodiment of the disclosure, an electronic device may include a first circuit board; a second circuit board including a first surface facing a first direction, and a second surface facing a second direction opposite to the first direction. The electronic device may include a first electronic component disposed between the first circuit board and the second circuit board, and including a plurality of pins disposed in the first area of the second circuit board for electrical connection with other components; and a second electronic component including a plurality of second pins disposed in the second area of the second circuit board for electrical connection with other components. The electronic device may include a heat dissipation device comprising a heat dissipating material disposed on a first surface of the second circuit board. The electronic device may include the first electronic component connected to the first circuit board through the plurality of first pins, and the second electronic component connected to the second circuit board through the plurality of second pins, wherein when the first electronic component and the second electronic component are disposed on the second circuit board, the plurality of first pins of the first electronic component, and the plurality of second pins of the second electronic component are formed to face in opposite directions to each other.

According to an embodiment of the disclosure, an electronic device may include a first circuit board having a first area corresponding to a first electronic component and a second area, non-overlapped with the first area, corresponding to a second electronic component; a second circuit board including a first surface facing a first direction, a second surface facing a second direction opposite to the first direction and facing the first circuit board; and a heat dissipation device disposed above the first surface of the second circuit board, the heat dissipation device connected with the first electronic component via a first TIM (thermal interface material). The first electronic component may be electrically connected with the first circuit board and second circuit board, and is disposed between the first circuit board and at least portion of the second circuit board. The second electronic component may be electrically connected with the second circuit board and, is disposed between the first circuit board and at least portion of second circuit board, such that the first electronic component and the second electronic component are electrically connected through the second circuit board.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2A is a front perspective view illustrating an electronic device, according to various embodiments;

FIG. 2B is a rear perspective view illustrating an electronic device, according to various embodiments;

FIG. 3 is an exploded perspective view of an electronic device according to various embodiments;

FIG. 4 is a cross-sectional view of a semiconductor package heat dissipation structure, according to an embodiment;

FIG. 5 is a diagram illustrating a surface of a second circuit board, according to an embodiment;

FIG. 6 is a diagram illustrating a configuration in which a first electronic component and a second electronic component are coupled to a second circuit board, in a method of manufacturing a semiconductor package heat dissipation structure according to an embodiment;

FIG. 7 is a diagram illustrating a configuration in which the electronic components, the second circuit board, and the second TIM (thermal interface material) that are coupled in FIG. 6, are coupled to a first circuit board, in a method of manufacturing a semiconductor package heat dissipation structure according to an embodiment;

FIG. 8 is a diagram illustrating a combined semiconductor package heat dissipation structure, according to an embodiment;

FIG. 9 is a diagram illustrating a configuration in which the electronic components and the second circuit board that are coupled in FIG. 6 are coupled to a first circuit board, according to an embodiment;

FIG. 10 is a diagram illustrating a second TIM (thermal interface material) injected in a liquid form, according to an embodiment;

FIG. 11 is a diagram illustrating a combined semiconductor package heat dissipation structure, according to an embodiment;

FIG. 12 is a diagram illustrating a semiconductor package heat dissipation structure that further includes a heat dissipation plate and a third TIM (thermal interface material), according to an embodiment;

FIG. 13 is a diagram illustrating a heat dissipation plate and a second circuit board, according to an embodiment;

FIG. 14 is a diagram illustrating a configuration in which the electronic components, the second circuit board, and a spacer that are coupled in FIG. 6, are coupled to a first circuit board, according to an embodiment;

FIG. 15 is a diagram illustrating a SIP structure that further includes a spacer according to an embodiment;

FIG. 16 is a diagram illustrating a semiconductor package heat dissipation structure according to an embodiment;

FIG. 17 is a diagram illustrating a semiconductor package heat dissipation structure that further includes a heat dissipation plate and a third TIM (thermal interface material), according to an embodiment;

FIG. 18 is a graph showing junction temperature according to an embodiment;

FIG. 19A is a graph showing peak performance of an electronic component according to an embodiment;

FIG. 19B is a graph showing peak performance of an electronic component, according to an embodiment;

FIG. 20 is a graph of power and temperature of an electronic component, according to an embodiment;

FIG. 21A is a diagram illustrating a surface temperature of an electronic device, according to an embodiment; and

FIG. 21B is a diagram illustrating a surface temperature of an electronic device, according to an embodiment.

FIG. 22 illustrates a cross-section of the semiconductor package heat dissipation, according to an embodiment.

FIG. 23 illustrates a surface of the second printed circuit board, according to an embodiment.

FIG. 24 illustrates a cross-section of the semiconductor package heat dissipation, according to an embodiment.

FIG. 25 illustrates a surface of the second printed circuit board, according to an embodiment.

Throughout the accompanying drawings, similar reference numbers may be assigned to similar components, configurations, and/or structures.

### DETAILED DESCRIPTION

The following description made with reference to the appended drawings is provided to assist in a comprehensive understanding of various embodiments of the disclosure. It includes various details to assist in that understanding but these are to be regarded as merely examples. Accordingly, those of ordinary skill in the art will recognize that various changes and modifications of the various embodiments described herein may be made without departing from the scope and spirit of the disclosure. In addition, descriptions of well-known functions and configurations may be omitted for clarity and conciseness.

The terms and words used in the following description and claims are not limited to the bibliographical meanings, but, are merely used to enable a clear and consistent understanding of the disclosure. Accordingly, it should be apparent to those skilled in the art that the following description of various embodiments of the disclosure is provided for illustration purpose only and not for the purpose of limiting the disclosure.

It is to be understood that the singular forms “a”, “an”, and “the” include plural referents unless the context clearly dictates otherwise. Thus, for example, reference to “a component surface” includes reference to one or more of such surfaces.

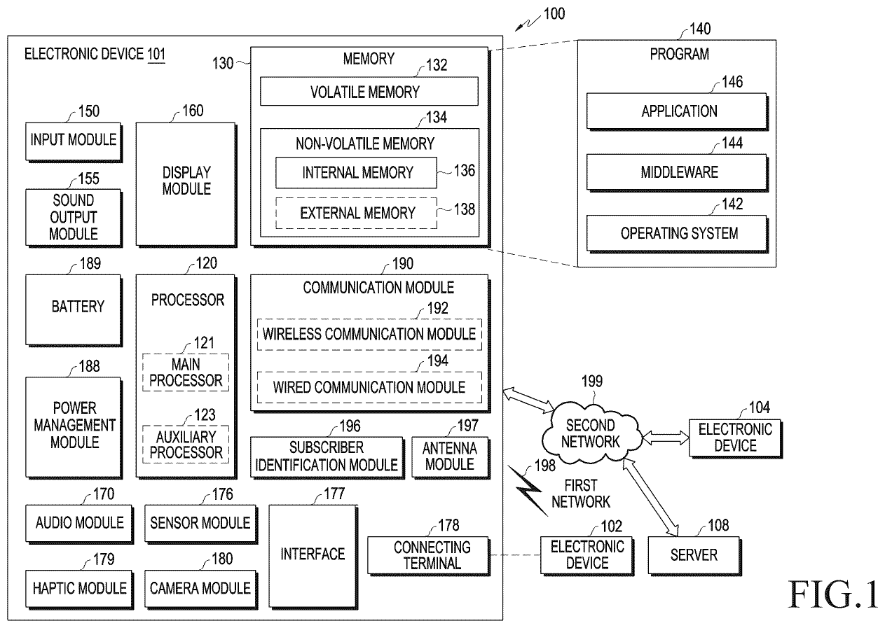

FIG. 1 is a block diagram illustrating an example electronic device 101 in a network environment 100 according to various embodiments of the disclosure. Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (cMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

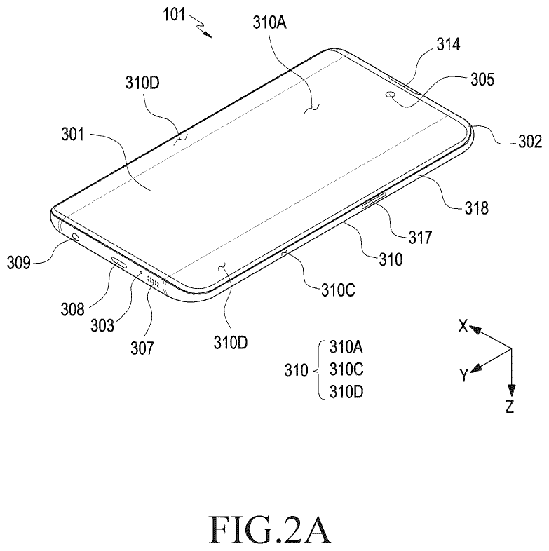

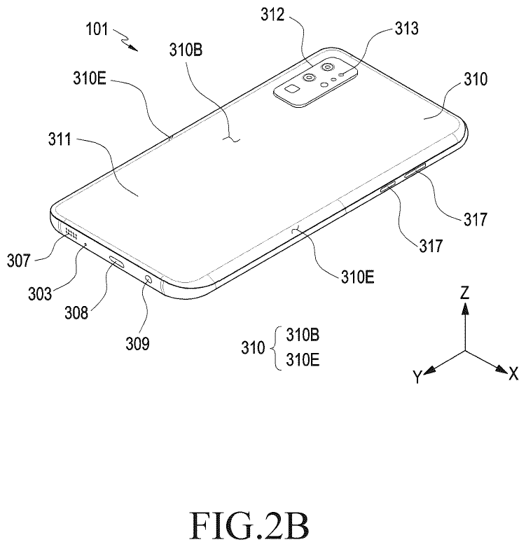

FIG. 2A is a front perspective view illustrating an electronic device 101 according to various embodiments. FIG. 2B is a rear perspective view illustrating the electronic device 101 according to various embodiments.

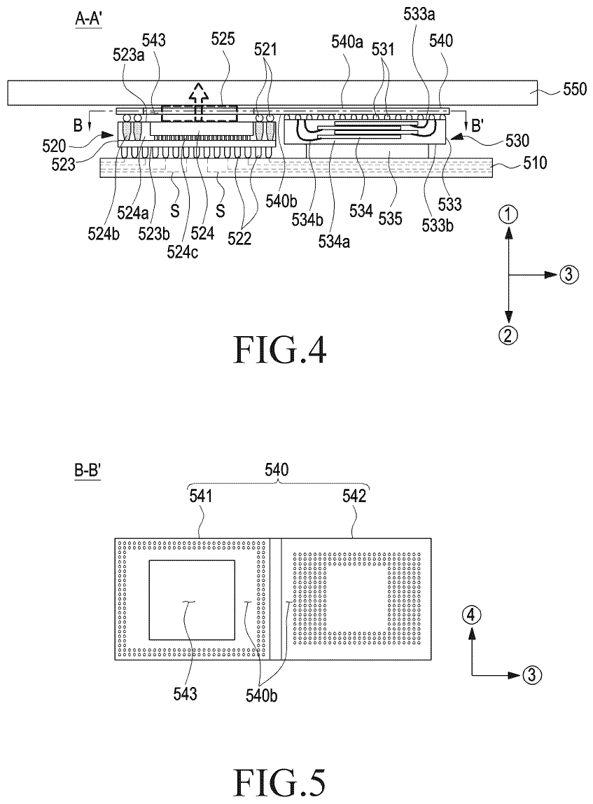

In the following descriptions, the vertical width direction of an electronic device 101 may refer to the “Y-axis direction”, the horizontal width direction may refer to the “X-axis direction”, and/or the height direction may refer to the “Z-axis direction”. In connection with the description of the directions, if “negative/positive (−/+)” is not described, it may be interpreted as including both the + direction and the − direction unless otherwise defined. That is, the “X-axis direction” may be interpreted as including both the +X and the −X directions, the “Y-axis direction” may be interpreted as including both the +Y and the −Y directions, and the “Z-axis direction” may be interpreted as including both the +Z direction and the −Z direction. In connection with the description of the directions, facing any one of the three-axes of an orthogonal coordinate system may include facing a direction parallel to the axis. In connection with the description of the drawings, although the arrangement of components may be based on the orthogonal coordinate system illustrated in the drawings, it should be noted that the directions or descriptions of elements do not limit the various embodiments of the disclosure. The first circuit board 510, the first electronic component 520, the second circuit board 540, and the heat dissipation device 550 illustrated in FIG. 4 which will be described below, are sequentially stacked in the first direction \textcircled{1}. In this case, the first direction (\textcircled{1}) may correspond to the height direction of the electronic device or a direction opposite to the height direction. However, this is only for easy of understanding of the semiconductor package heat dissipation structure of the disclosure, and does not limit a specific direction. For example, it should be noted that the first direction \textcircled{1} may include directions other than the height direction of the electronic device.

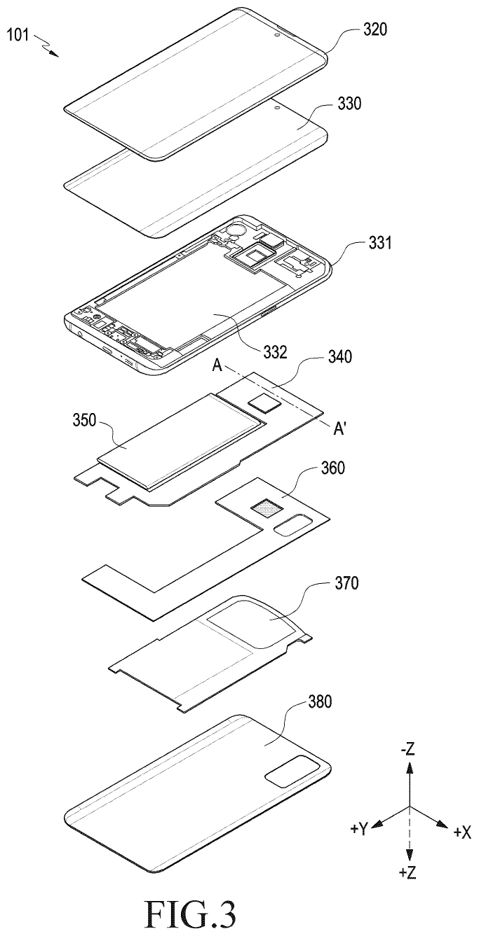

Referring to FIGS. 2A and 2B, an electronic device 101 according to an embodiment may comprise a housing 310 including a front surface 310A, a rear surface 310B, and a side surface 310C surrounding a space defined between the front surface 310A and the rear surface 310B. In an embodiment (not shown), the housing 310 may refer to a structure that forms some of the front surface 310A of FIG. 2, the rear surface 310B and the side surface 310C of FIG. 3. According to an embodiment, at least a portion of the front surface 310A may be formed by a substantially transparent front plate 302 (e.g., a glass plate or a polymer plate including various coating layers). The rear surface 310B may be formed by a rear plate 311. The rear plate 311 may be formed of, for example, glass, ceramic, a polymer, or a metal (e.g., aluminum, stainless steel (STS), or magnesium), or a combination of two or more of these materials. The side surface 310C may be formed by a side bezel structure 318 (or “a side member”) coupled to the front plate 302 and the rear plate 311 and including a metal and/or a polymer. In an embodiment, the rear plate 311 and the side bezel structure 318 may be integrally formed, and include the same material (e.g., a metal material such as glass, and aluminum or ceramic).

In the illustrated embodiment, the front plate 302 may include two first areas 310D, which seamlessly and bendingly extend from the front surface 310A towards the rear plate 311, on both the long edges of the front plate 302. In the illustrated embodiment (see FIG. 3), the rear plate 311 may include two second areas 310E, which bendingly and seamlessly extend from the rear surface 310B towards the front plate 302, on both the long edges thereof. In an embodiment, the front plate 302 (or the rear plate 311) may include only one of the first areas 310D (or the second areas 310E). In another embodiment, some of the first areas 310D or the second areas 310E may not be included. In the above embodiments, when viewed from a side of the electronic device 101, the side bezel structure 318 may have a first thickness (or width) for a side that does not include the first areas 310D or the second areas 310E, and may have a second thickness, which is smaller than the first thickness, for a side that includes the first areas 310D or the second areas 310E.

According to an embodiment, the electronic device 101 may include at least one or more of a display 301, an audio module (e.g., a microphone hole 303 and speaker holes 307 and 314) (e.g., the audio module 170 of FIG. 1), a sensor module (e.g., the sensor module 176 of FIG. 1), a camera module (e.g., camera modules 305, 312), and a flash 313 (e.g., the camera module 180 of FIG. 1), a key input device 317 (e.g., the input module 150 of FIG. 1) and connector holes 308 and 309 (e.g., the connection terminal 178 of FIG. 1). In an embodiment, at least one of the components (e.g., the connector hole 309) may be omitted from the electronic device 101, or the electronic device 101 may additionally include other components.

According to an embodiment, the display 301 may be visually exposed (e.g., visible), for example, through a large portion of the front plate 302. In an embodiment, at least a portion of the display 301 may be exposed (e.g., visible) through the front surface 310A, and the front plate 302 forming the first areas 310D. As used herein with reference to the display, the terms “visually exposed”, “exposed”, “visible”, etc. may be used interchangeably and include an arrangement including a front or cover plate or layer. In an embodiment, the edges of the display 301 may be formed to be substantially the same as the contour shape of the front plate 302 adjacent thereto. In another embodiment (not shown), the interval between the outer edge of the display 301 and the outer edge of the front plate 302 may be formed to be substantially constant in order to enlarge the visually exposed (e.g., visible) area of the display 301.

According to an embodiment, the surface of the housing 310 (or the front plate 302) may include a screen display area formed as the display 301 is visually exposed (e.g., visible). For example, the screen display area may include the front surface 310A and first edge areas 310D.

According to an embodiment (not shown), the screen display area (e.g., the front surface 310A) of the display 301 may form a recess or an opening in a portion of the first edge areas 310D, and may include at least one or more of the audio module (e.g., the speaker hole 314), a sensor module (not shown), a light-emitting element (not shown), and the camera module 305, which are aligned with the recess or the opening. In an embodiment (not shown), at least one or more of the audio module (e.g. the speaker hole 314), the sensor module (not shown), the camera module 305, the fingerprint sensor (not shown), and the light-emitting element (not shown) may be included on the rear surface of the screen display area of the display 301.

In an embodiment (not shown), the display 301 may be coupled to or disposed adjacent to a touch-sensing circuit, a pressure sensor capable of measuring the intensity of the touch (pressure), and/or a digitizer detecting a magnetic field type stylus pen.

In an embodiment, at least a portion of the key input device 317 may be disposed in the first edge areas 310D and/or the second edge areas 310E.

According to an embodiment, the audio modules (e.g., a micro hole 303, and speaker holes 307, and 314) may include, for example, a microphone hole 303 and speaker holes 307 and 314. The microphone hole 303 may include a microphone disposed therein so as to acquire external sound, and in an embodiment, a plurality of microphones may be disposed therein to be able to detect the direction of a sound. The speaker holes 307 and 314 may include an external speaker hole 307 and a phone call receiver hole 314. In an embodiment, the speaker holes 307 and 314 and the microphone hole 303 are implemented as a single hole, or a speaker may be included without the speaker holes 307 and 314 (e.g., a piezo speaker). The audio modules 303, 307, and 314 may be designed in various manners such as installation of only some audio modules or addition of a new audio module according to the structure of the electronic device 101, not limited to the above structure.

According to an embodiment, sensor modules (not shown) may generate an electrical signal or a data value corresponding to, for example, an internal operating state or external environmental state of the electronic device 101. The sensor modules (not shown) may include, for example, a first sensor module (not shown) (e.g., a proximity sensor) and/or a second sensor module (not shown) (e.g., a fingerprint sensor) which are disposed on the front surface 310A of the housing 310, and/or a third sensor module (not shown) (e.g., an HRM sensor), and/or a fourth sensor module (not shown) (e.g., a fingerprint sensor) which are disposed on the rear surface 310B of the housing 310. In an embodiment (now shown), the fingerprint sensor may be disposed not only on the front surface 310A (e.g., the display 301) of the housing 310, but also on the rear surface 310B. The electronic device 101 may further include at least one of the sensor modules which are not shown, such as a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, and an illuminance sensor (not shown). The sensor modules (not shown) may be designed in various manners such as installation of only some sensor modules or addition of a new sensor module according to the structure of the electronic device 101, not limited to the above structure.

According to an embodiment, the camera modules (e.g., the camera modules 305, and 312, and the flash 313) may include, for example, a front camera module 305 disposed on the front surface 310A of the electronic device 101, and a rear camera module 212 and/or a flash 313 disposed on the rear surface 310B. The camera modules 305 and 312 may include one or more lenses, an image sensor, and/or an image signal processor. The flash 313 may include, for example, a light-emitting diode or a xenon lamp. In an embodiment, two or more lenses (e.g., an infrared camera lens, a wide-angle lens, and a telephoto lens) and image sensors may be disposed on one surface of the electronic device 101. The camera modules (e.g., the camera modules 305, and 312, and the flash 313) may be designed in various manners such as installation of only some camera modules or addition of a new camera module according to the structure of the electronic device 101, not limited to the above structure.

According to an embodiment, the electronic device 101 may include a plurality of camera modules (e.g., a dual camera or a triple camera) each having a different attribute (e.g., angle of view) or function. For example, a plurality of camera modules 305 and 312 including lenses having different angles of view may be configured, and the electronic device 101 may control to change of the angles of view of the camera modules 305 and 312 implemented in the electronic device 101 based on a user selection. For example, at least one of the plurality of camera modules 305 and 312 may be a wide-angle camera, and at least one other camera module may be a telephoto camera. Similarly, at least one of the plurality of camera modules 305 and 312 may be a front camera, and at least one other camera module may be a rear camera. Further, the plurality of camera modules 305 and 312 may include at least one of a wide-angle camera, a telephoto camera, or an IR camera (e.g., a time of flight (TOF) camera or a structured light camera). According to an embodiment, the IR camera may be operated as at least part of the sensor module. For example, the TOF camera may be operated as at least part of a sensor module (not shown) for detecting a distance to a subject.

According to an embodiment, the key input device 317 may be disposed on the side surface 310C of the housing 310. In an embodiment, the electronic device 101 may not include some or all of the above-mentioned key input device 317, and the key input device 317, which is not included therein, may be implemented in another form such as a soft key on the display 301. In an embodiment, the key input device may include a sensor module (not shown) disposed on the rear surface 310B of the housing 310.

According to an embodiment, the light emitting elements (not shown) may be disposed, for example, on the first surface 310A of the housing 310. The light emitting elements (not shown) may provide, for example, state information about the electronic device 101 in the form of light. In an embodiment, the light emitting elements (not shown) may provide a light source interworking, for example, with an operation of the front camera module 305. The light emitting elements (not shown) may include, for example, an LED, an IR LED, and/or a xenon lamp.

According to an embodiment, the connector holes 308 and 309 may include a first connector hole 308 that may accommodate a connector (e.g., a universal serial bus (USB) connector) for transmitting and receiving power and/or data to and from an external electronic device, and/or a second connector hole 309 (e.g., an earphone jack) that may accommodate a connector for transmitting and receiving an audio signal to and from an external electronic device. The connector holes 308 and 309 may be designed in various manners such as installation of only some connector hole or addition of a new connector hole according to the structure of the electronic device 101, not limited to the above structure.

According to an embodiment, a camera module 305 and/or a sensor module (not shown) may be disposed in the inner space of the electronic device 101 to come into contact with the external environment through a predetermined area of the display 301 and the front plate 302. For example, the predetermined area may be an area in which no pixels are disposed in the display 301. As another example, the predetermined area may be an area in which pixels are disposed in the display 301. When viewed from above the display 301, at least a portion of the predetermined area may overlap the camera module 305 and/or the sensor module. As another example, some sensor modules may be arranged in the inner space of the electronic device to implement the functions thereof without being visually exposed through the front plate 302.

FIG. 3 is an exploded perspective view illustrating the electronic device according to various embodiments.

Referring to FIG. 3, the electronic device 101 (e.g., the electronic device 101 of FIGS. 2A to 2B) may include a front plate 320 (e.g., the front plate 302 of FIG. 2A), a display 330 (e.g., the display 301 of FIG. 2A), a first support member 332 (e.g. a bracket) a main printed circuit board 340 (e.g., a PCB, a flexible PCB (FPCB), or a rigid flexible PCB (RFPCB)), a battery 350, a second support member 360 (e.g., a rear case), an antenna 370, and a rear plate 380 (e.g., the rear plate 311 of FIG. 3). In an embodiment, the electronic device 101 may not be provided with at least one (e.g., the first support member 332 or the second support member 360) of the components or additionally include other components. At least one of the components of the electronic device 101 may be the same as or similar to at least one of the components of the electronic device 101 of FIG. 2 or FIG. 3, and a redundant description will be omitted below.

According to an embodiment, the first support member 332 may be disposed inside the electronic device 101, and may be connected to or integrally formed with the side bezel structure 331. The first support member 332 may be formed of, for example, a metal material and/or a non-metal (e.g., polymer) material. The first support member 332 may have the display 330 coupled with one surface thereof and the printed circuit board 340 coupled with the other surface thereof. The printed circuit board 340 may have a processor, memory, and/or an interface mounted thereof. The processor may include, for example, at least one of a CPU, an application processor, a graphics processor, an image signal processor, a sensor hub processor, or a communication processor. According to an embodiment, the printed circuit board 340 may include a flexible printed circuit board-type radio frequency cable (FRC). For example, the printed circuit board 340 may be disposed on at least part of the first support member 332, and electrically connected to an antenna module (e.g., the antenna module 197 in FIG. 1) and a communication module (e.g., a communication module 190 in FIG. 1).

According to an embodiment, the memory may include, for example, volatile memory or non-volatile memory.

According to an embodiment, the interface may include, for example, a high definition multimedia interface (HDMI), a universal serial bus (USB) interface, an SD card interface, and/or an audio interface. The interface may, for example, electrically or physically connect the electronic device 101 to an external electronic device, and include a USB connector, an SD card/MMC connector, or an audio connector.

According to an embodiment, the battery 350 is a device for supplying power to at least one component of the electronic device 101, and may include, for example, a non-rechargeable primary battery, or a rechargeable secondary battery, or a fuel cell. At least part of the battery 350 may be positioned substantially on the same plane as the printed circuit board 340, for example. The battery 350 may be integrally disposed inside the electronic device 101 or detachably from the electronic device 101.

According to an embodiment, the second support member 360 (e.g., the rear case) may be disposed between the printed circuit board 340 and the antenna 370. For example, the second support member 360 may include one surface with which at least one of the printed circuit board 340 or the battery 350 is coupled, and the other surface with which the antenna 370 is coupled.

According to an embodiment, the antenna 370 may be disposed between the rear plate 380 and the battery 350. The antenna 370 may include, for example, a near field communication (NFC) antenna, a wireless charging antenna, and/or a magnetic secure transmission (MST) antenna. The antenna 370 may, for example, perform short-range communication with an external device or wirelessly transmit and receive power required for charging. For example, the antenna 370 may include a coil for wireless charging. In an embodiment, an antenna structure may be formed by part of the side bezel structure 331 and/or part of the first support member 332 or a combination thereof.

According to an embodiment, the rear plate 380 may form at least part of the rear surface (e.g., the second surface 310B of FIG. 2B) of the electronic device 101.

Although the electronic device 101 illustrated in FIG. 2A to FIG. 3 has a bar-type or plate-type exterior, various embodiments of the disclosure are not limited thereto. For example, the illustrated electronic device may be a part of a rollable electronic device or a foldable electronic device. The “rollable electronic device” may refer to an electronic device that has a deformable display so that at least a portion of the display is capable of being wound or rolled or capable of being accommodated into the housing 310. According to a user's need, the rollable electronic device may be used in the state in which the screen display area is expanded by unfolding the display or exposing a larger area of the display to the outside. A “foldable electronic device” may refer to an electronic device in which two different areas of the display are foldable to face each other or to be oriented in directions opposite to each other. In general, in the foldable electronic device in a carried state, the display is folded in the state in which two different areas face each other or in opposite directions, and in actual use, the user may unfold the display such that the two different areas form a substantially flat plate shape. In an embodiment, the electronic device 101 according to various embodiments disclosed herein may be interpreted as including not only a portable electronic device such as a smartphone, but also various other electronic devices such as a notebook computer or a home appliance.

Hereinafter, a structure for efficiently dissipating high-temperature heat while increasing an efficiency of a mounting space inside the electronic device 101 will be described in greater detail below with reference to the embodiments of FIGS. 4 to 17. In this case, the “structure” may be a semiconductor package heat dissipation structure including a plurality of components, and the plurality of components may be configured as a system in package (SIP).

FIG. 4 is a cross-sectional view of a semiconductor package heat dissipation structure according to an embodiment. FIG. 5 is a diagram illustrating a surface of a second circuit board according to an embodiment. FIG. 4 is a cross-sectional view of a portion of the electronic device shown in FIG. 3, taken along line A-A′, and FIG. 5 is a cross-sectional view of the semiconductor package heat dissipation structure shown in FIG. 4, taken along line B-B′.

According to an embodiment, an electronic device (e.g., the electronic device 101 of FIGS. 1 to 3) has a semiconductor package heat dissipation structure, and may include a first circuit board 510 and a second circuit board 540.

Various components may be mounted on a first circuit board 510 (e.g., a main circuit board). For example, a processor (e.g., the processor 120 of FIG. 1), a memory (e.g., the memory 140 of FIG. 1), and/or an interface (e.g., the interface 177 of FIG. 1) may be mounted, disposed and/or disposed on the first circuit board 510. The first circuit board 510 may include a printed circuit board (PCB) or a flexible PCB (FPCB). According to an embodiment, the first circuit board may be referred to as a first printed circuit board (PCB) or a first flexible printed circuit board (FPCB). The processor may include, for example, at least one or more of a CPU, an application processor, a graphics processor, an image signal processor, a sensor hub processor, or a communication processor. The memory may include, for example, volatile memory or non-volatile memory. The interface may include, for example, a high definition multimedia interface (HDMI), a universal serial bus (USB) interface, an SD card interface, and/or an audio interface. The interface may, for example, electrically or physically connect the electronic device 101 to an external electronic device, and include a USB connector, an SD card/MMC connector, or an audio connector. One or more of the above-described components may be omitted from the first circuit board 510 or other components not described above may be mounted on the first circuit board 510.

Hereinafter, the following describes an embodiment in which the first electronic component (520) includes at least one of an application processor and/or a communication processor, and the second electronic component (530) includes memory. The application processor and/or the communication processor may be connected to the memory via signal lines. The application processor and/or the communication processor can efficiently transmit and receive large amounts of data frequently and rapidly via the memory and signal lines. In this case, the heat generated by the application processor and/or the communication processor may exceed that generated by the memory.

The second circuit board 540 may include a printed circuit board (PCB) or a flexible PCB (FPCB). According to an embodiment, the second circuit board may be referred to as a second printed circuit board (PCB) or a second flexible printed circuit board (FPCB). The second circuit board 540 may be at least partially stacked on the first circuit board 510, while being spaced from the first circuit board 510 by a predetermined distance towards the first direction (1). As a result, the second circuit board 540 and the first circuit board 510 may form a multilayer board structure. The second circuit board 540 may serve as an interposer, facilitating electrical connections between a semiconductor chip and a circuit board, and/or providing flexibility in utilizing a component mounting space to achieve the electrical connection of the multilayer board structure. By utilizing the second circuit board 540 to form a multilayer board structure, it is possible to effectively utilize the limited arrangement space within the electronic device.

The second circuit board 540 may accommodate a plurality of electronic components. Referring to FIG. 5, the second circuit board 540 may include a first area 541, and a second area 542 which is different from the first area 541. Two electronic components (e.g. the first electronic component 520 and the second electronic component 530) may be arranged separately in the first area 541 and the second area 542, respectively. For instance, the first electronic component 520 may be disposed in the first area 541, and the second electronic component 530 may be disposed in the second area 542. According to an embodiment, the first area 541 and the second area 542 may not overlap. According to an embodiment, the first area 541 and the second area 542 may be formed independently without overlapping. According to an embodiment, the first electronic component 520 and the second electronic component 530, which are disposed on the second circuit board 540, may be electrically connected through signal lines (or data lines). The signal lines may be configured to pass through the inside of the second circuit board 540, including at least one conductive line. The signal lines penetrate through the inside of the second circuit board 540, with one side of the signal line connected to the first electronic component 520 and the other side connected to the second electronic component 530.

According to an embodiment, the first electronic component 520 and/or the second electronic component 530 may be disposed between one surface of the first circuit board 510 and one surface of the second circuit board 540.

The second circuit board 540 may include a first surface 540a facing a first direction \textcircled{1} and a second surface 540b facing a second direction \textcircled{2} opposite to the first direction. The first electronic component 520 and the second electronic component 530 may be disposed on the second surface 540b of the second circuit board 540. According to an embodiment, the first electronic component 520 and/or the second electronic component 530 may be positioned on substantially the same plane on the second circuit board 540.

The types and shape of electronic components that may be disposed on the second circuit board 540 are not limited to any specific ones. These electronic components may include, for example, a communication device, a processor, a memory, a radio frequency front end (RFFE), an RF transceiver, a power management module, a wireless communication circuit, and/or an interface. The processor may include one or more of a central processing unit, an application processor, a graphics processing unit, an image signal processor, a sensor hub processor, or a communication processor, for example. According to an embodiment, the processor may include at least a communication processor, or may have a configuration in which an application processor and a communication processor are integrated, and may control or operate the wireless transceiver, power management module, or wireless communication circuit. The electronic component module may include a plurality of electronic components or elements for implementing at least one function. In FIG. 4 and subsequent drawings, an application processor including a flip chip in the form of a system on chip (SoC) is disclosed as an example of the first electronic component 520, and a memory is disclosed as an example for the second electronic component 530. However, it should be noted that such disclosure does not limit the scope of the first electronic component 520 and the second electronic component 530 according to an embodiment of the disclosure.

According to an embodiment, the electronic device (e.g., the electronic device 101 in FIGS. 1 to 3) may include a semiconductor package heat dissipation structure comprising a heat dissipation device 550, a first TIM (thermal interface material) 525, and a second TIM (thermal interface material) 535.

The heat dissipation device 550 may be disposed on the first surface 540a of the second circuit board 540. The heat dissipation device 550 may be, for example, a vapor chamber. Although not shown in the drawings, at least a portion of the heat dissipation device 550 may be supported by a support member (e.g., the first support member 332 of FIG. 3 (e.g., a bracket)), a second support member 360 (e.g., the rear case), a printed circuit board (e.g., 510, and 540), and/or a housing (e.g., the housing 310 of FIG. 3) of an electronic device (e.g., the electronic device 101 of FIG. 1). At least a portion of the heat dissipation device 550 may face a surface of the electronic component (e.g., the first electronic component 520 and the second electronic component 530) from which heat is radiated. The heat dissipation device 550 may receive high-temperature heat and, because the inside is vacuum-sealed, the heat received from the electronic component may be rapidly diffused in a horizontal direction (e.g., direction (3)). For instance, the heat dissipation device 550 may be a heat conductor that has a vacuum inside and contains a working fluid.

When heat is applied to any part of the heat dissipation device 550, the phenomenon may be utilized that the working fluid in liquid state evaporates, and the resulting pressure difference causes the working fluid in a gaseous state to quickly move to an area with relatively low temperature. Although a vacuum chamber was given as an example of the heat dissipation device 550, the embodiment of the heat dissipation device 550 is not necessarily limited thereto. In addition to the vacuum chamber, the heat dissipation device 550 may include various heat transfer materials or members such as solid phase thermal sheets (e.g., heat pipes, graphene sheets, graphite sheets, metal (e.g., copper) sheets) or liquid phase heat-dissipating paints. Alternatively, the heat dissipation device 550 may also be a part of the metal housing. In this case, heat transfer through various heat transfer materials or members may involve at least some of the various forms of thermal energy movement, including heat conduction, heat spreading, heat diffusion, or heat radiation.

The first TIM 525 and the second TIM 535 may be provided to dissipate heat from the first electronic component 520 and the second electronic component 530, respectively. According to an embodiment, the first TIM 525 is disposed in the first opening 543 formed in the first area 541 of the second circuit board 540, and configured to transfer the heat from the first electronic component 520 to the heat dissipation device 550. The second TIM 535 is disposed between the second electronic component 530 and the first circuit board 510, and configured to transfer heat from the second electronic component 530 to the first circuit board 510. According to an embodiment of the disclosure, the first TIM 525 may function to dissipate heat from a surface of the first electronic component 520 facing the first direction (\textcircled{1}) towards the heat dissipation device 550, and the second TIM 535 may function to dissipate heat towards the first circuit board 510 from a surface of the second electronic component 530 facing the second direction (\textcircled{2}). According to an embodiment of the disclosure, an electronic device (e.g., electronic device 101 in FIGS. 1-3) may have high heat dissipation efficiency by including the first TIM 525 and the second TIM 535 that dissipate heat in different directions.

According to an embodiment, the first TIM 525 and/or the second TIM 535 may include at least one of carbon fiber thermal interface material, liquid phase thermal interface material, acrylic thermal interface material, and/or solid phase thermal interface material. For instance, the first TIM 525 may be a carbon fiber TIM, and the second TIM 535 may be an acrylic TIM.

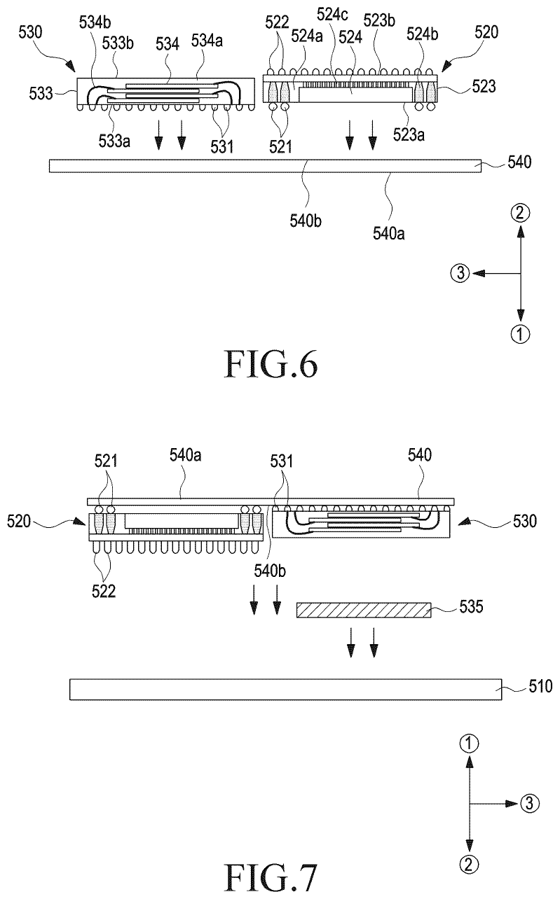

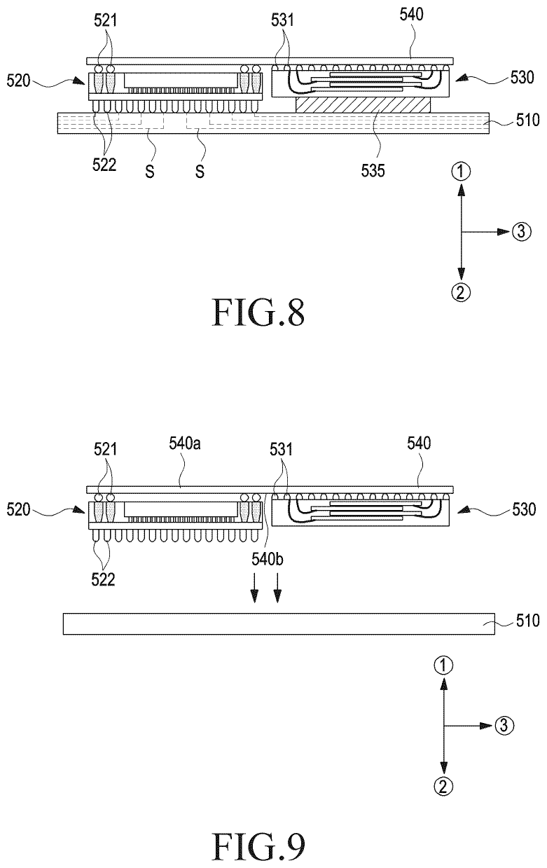

FIG. 6 is a diagram illustrating an example method of manufacturing a heat dissipation structure for a semiconductor package according to an embodiment, where the first and second electronic components are coupled to the second circuit board. FIG. 7 is a diagram illustrating an example method of manufacturing a heat dissipation structure for a semiconductor package according to an embodiment, where the electronic components, the second circuit board, and the second heat transfer member that are coupled in FIG. 6, are coupled to the first circuit board. FIG. 8 is a diagram illustrating a combined the semiconductor package heat dissipation structure according to an embodiment.

Referring to FIGS. 6, 7 and 8, a method for manufacturing a heat dissipation structure for a semiconductor package will be described according to an embodiment of the disclosure. With reference to FIG. 6, first, the first electronic component 520 and the second electronic component 530 may be disposed on the second surface 540b of the second circuit board. Each of the first electronic component 520 and the second electronic component 530 may include a plurality of pins (e.g., lead frames) for electrical connection with other components. For instance, the first electronic component 520 may be an integrated circuit including a first case 523, a first chip 524 located inside the first case 523, and a first pin 521, 522 provided for electrical connection with other components outside the first case 523. The first pin 521, 522 includes a (1-1) th pin 521 (may referred as a first first pin 521) and a (1-2) th pin 522 (may referred as a second first pin 521). The first electronic component 520 may be connected to the first circuit board 510 via the (1-1) th pin 521 and to the second circuit board 540 via the (1-2) th pin 521. Through the first pin 521, 522, the first electronic component (520) may be electrically and/or physically connected to both the first circuit board (510) and the second circuit board (540). The first pins 521, 522 may be composed of a plurality of first pins 521, 522. According to an embodiment, the first electronic component 520 may be a package containing the first chip 524. In an embodiment, the first electronic component 520 may be a single component consisting of the first chip 524 itself.

The first chip 524 may be encapsulated by an epoxy resin 524a and may be a flip chip mounted using solder balls (or solder bumps) 524c. The first chip 524 may be electrically connected to the first circuit board 510 using solder balls 524c. The solder balls 524c are formed on a surface of the first chip 524 toward the second surface 523b of the first case 523 facing in the first circuit board 510. The first electronic component 520 may have at least one via 524b that provides an electrical connection between the plurality of (1-1) th pins 521 formed on the first surface 523a of the first case 523 and the plurality of (1-2) th pins 522 formed on the second surface 523b of the first case 523. The plurality of (1-1) th pins 521 and the plurality of (1-2) th pins 522 may be solder balls (or solder bumps). Referring to FIG. 6, the plurality of (1-1) th pins 521 formed on the first surface 523a of the first case 523 and the plurality of (1-2) th pins 522 formed on the second surface 523b of the first case 523 may be formed of solder balls (or solder bumps) having different sizes, but are not necessarily limited thereto, and may also be formed of solder balls (or solder bumps) having the same size according to embodiments. The second electronic component 530 may be an integrated circuit including a second case 533, a second chip 534 located within the second case 533, and a second pin 531 provided for electrical connection with other components outside the second case 533. Through the second pin 531, the second electronic component may be electrically and/or physically connected to the second circuit board 540. The second pin 531 may include a plurality of second pins 531. The second chip 534 may be encapsulated by an epoxy resin 534a. The second chip 534 may be a component such as a memory (e.g., the memory 130 of FIG. 1) (e.g., DRAM). The second electronic component 530 may include a structure in which a plurality of second chips 534 are stacked with each other. The second chip 534 may be connected to the second circuit board 540 using a wire 534b. The wire 534b are wired from the the second chip 534 to the first surface 533a of the second case 533 facing in the second circuit board 520. The second pin 531 may be formed on the first surface 533a of the first surface 533a and the second surface 533b of the second case 533. The second pin 531 may be a solder ball (or solder bump). According to an embodiment, the first electronic component 520 may be connected to the second circuit board 540 through the (1-1) th pins 521, and the second electronic component 530 may be connected to the second circuit board 540 through the second pin 531.

Referring to FIG. 6, the first electronic component 520 and the second electronic component 530 may face in opposite directions when assembled (or electrically connected) to the second circuit board 540, based on the electrical connection direction of the chip embedded in each component. According to an embodiment, the first chip 523 of the first electronic component 520 may include an electrical connection path formed in a direction toward the second surface 523b of the first case 523, using a solder ball (524c) formed in a direction from the first chip 523 toward the second surface 523b of the first case 523. According to an embodiment, the second chip 533 of the second electronic component 530 may include an electrical connection path formed in a direction toward the first surface 533a of the second case 533, using a wire (534b) extending from the second chip 533 toward the first surface 533a of the second case 533. By assembling the first electronic component 520 and the second electronic component 530 in opposite directions on the second circuit board 540, it is possible to implement a heat dissipation structure in opposite directions using the first TIM 525 and the second TIM 535. In accordance with an embodiment, the first electronic component 520 may be connected not only to the first circuit board 510 through the plurality of (1-2) th pins 522 formed on the second surface 523b of the first case 523, but may also be electrically connected to the second circuit board 540 through the plurality of (1-1) th pins 521 formed on the first surface 523a of the first case 523, to thereby be electrically connected to the second electronic component 530 through the second circuit board 540.

In FIG. 6, it is illustrated that the first electronic component 520 and the second electronic component 530 are assembled on the second surface 540b of the second circuit board 540. Herein, the first electronic component 520 may be assembled to the second circuit board 540 through the plurality of (1-1) th pins 521, and the second electronic component 530 may be assembled to the second circuit board 540 through a plurality of second pins 531. Here, the term “assembly” may refer, for example, to a structure in which a first component (e.g., the first electronic component 520) and a second component (e.g., the second electronic component 530) are connected to form a single structure, which may not necessarily be a finished product that implements a certain function, but rather may be an intermediate structure. Additionally, the term “assembly” may be interpreted in various ways, such as coupling, fastening, attaching, joining, assembling, or installing. Henceforth, the assembly of the first electronic component 520 and the second electronic component 530 on the second circuit board 540 will be referred to as an “intermediate assembly” of the electronic components 520 and 530 and the second circuit board 540.

Referring to FIGS. 7 and 8 together, the intermediate assembly shown in FIG. 6 is reversed (e.g., the second surface 540b of the second circuit board 450 facing the first circuit board 510), allowing the plurality of (1-1) th pins 521 of the first electronic component 520 to be coupled to the first circuit board 510 in a state facing the first circuit board 510. According to an embodiment, when the intermediate assembly is mounted on the first circuit board 510, the second TIM 535 may also be mounted on the first circuit board 510. In the embodiments shown in FIGS. 7 and 8, the second TIM 535 mounted on the first circuit board 510 may be a solid TIM 535.

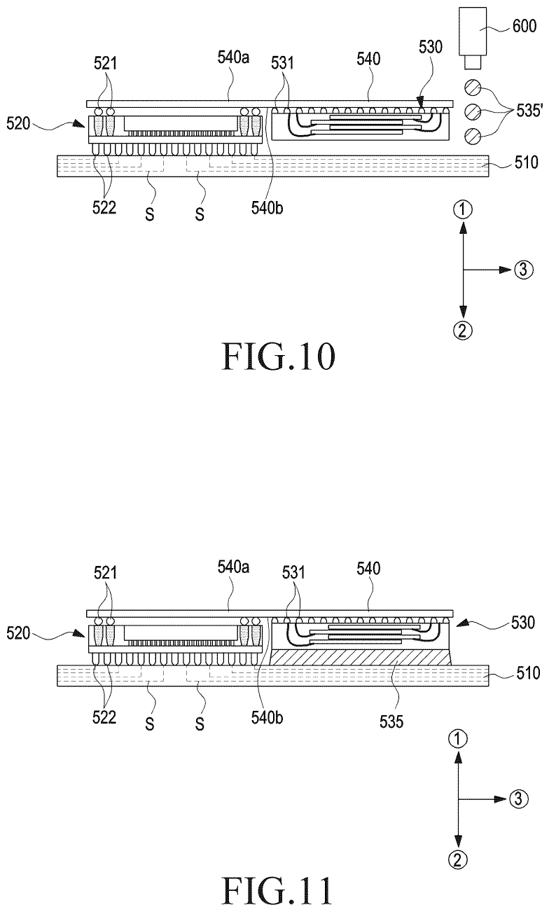

FIG. 9 is a diagram illustrating a state in which the electronic components and the second circuit board combined in FIG. 6 are coupled to the first circuit board according to an embodiment. FIG. 10 is a diagram illustrating a second TIM injected in liquid form according to an embodiment. FIG. 11 is a diagram illustrating a combined semiconductor package heat dissipation structure according to an embodiment.

FIGS. 9, 10 and 11 illustrate using a liquid TIM 535′ as the second TIM 535. Using a liquid TIM 535′ makes it easier to form the second TIM 535 with a height corresponding to a level difference between components.

According to an embodiment, a liquid TIM 535′ may be dropped through a nozzle 600 to fill the lower portion of the second electronic component 530 in a state where the intermediate assembly of the electronic components 520 and 530 and the second circuit board 540 is mounted on the first circuit board 510. The filled liquid TIM 535′ may gradually solidify over time to become a solid TIM 535.

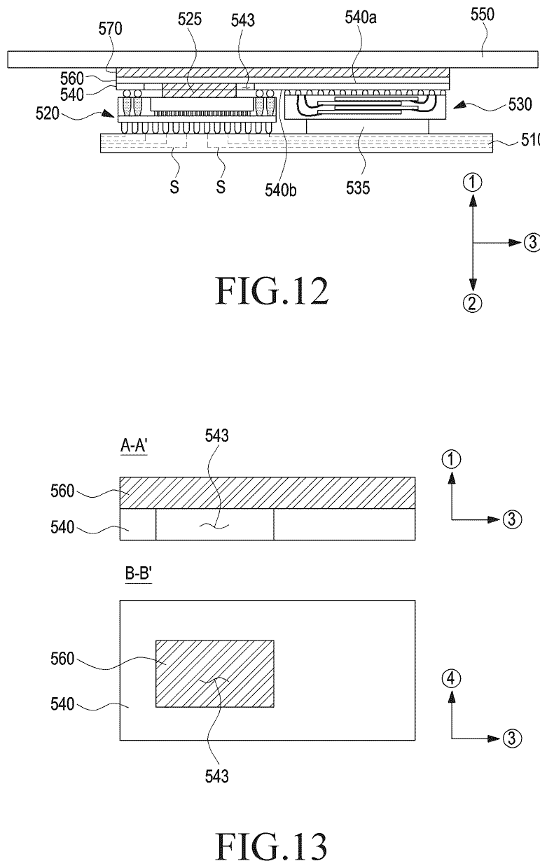

FIG. 12 is a diagram illustrating a semiconductor package heat dissipation structure that further includes a heat dissipation plate and a third TIM (thermal interface material), according to various embodiments. FIG. 13 is a diagram illustrating a heat sink plate and a second circuit board according to an embodiment.

According to an embodiment, the semiconductor package heat dissipation structure described in FIGS. 4 to 11 may further include a heat dissipation plate 560 and a third TIM (thermal interface material) 570. When heat generated from the first electronic component 520 passes through the first TIM 525, the heat dissipation plate 560 primarily serves to dissipate the heat passing through the first TIM 525. By dispersing the heat primarily in the heat dissipation plate 560 disposed between the first TIM 525 and the heat dissipation device 550 before transferring the heat passing through the first electronic component 520 and the first TIM 525 to the heat dissipation device 550, heat may be smoothly spread. According to an embodiment, the heat dissipation plate 560 may be referred to as a heat spreader.

According to an embodiment, the heat dissipation plate 560 may include a metallic material. Additionally, according to an embodiment, the heat dissipation plate 560 may be formed to have an area that substantially corresponds to the second circuit board 540 and may be attached to the first surface 540a of the second circuit board 540. In an embodiment, the arrangement of the first electronic component 520 and the second electronic component 530 may cause a warpage phenomenon to occur in the second circuit board 540. To address this, the heat dissipation plate 560, which includes a metallic material, is formed to be attached to the first surface 540a of the second circuit board 540, as in an embodiment of the disclosure, to prevent and/or reduce the warpage phenomenon. Referring to FIG. 13, the heat dissipation plate 560 is attached to the first surface 540a of the second circuit board 540, and at this point, the first opening 543 may be formed only on the second circuit board 540.

According to an embodiment, the third TIM 570 may be disposed between the heat dissipation device 550 and the heat dissipation plate 560. Similar to the heat dissipation plate 560, the third TIM 570 may also be formed to correspond to an area substantially corresponding to the second circuit board 540. The entire area of the heat dissipation plate 560 may be attached to the heat dissipation device 550 through the third TIM 570, so that the heat primarily dispersed from the heat dissipation plate 560 may be transferred to the heat dissipation device 550 through the third TIM 570, and the heat dissipation device 550 may secondarily dissipate the transferred heat. The third TIM 570 may be at least one of carbon fiber thermal interface material (TIM), liquid phase thermal interface material (TIM), acrylic thermal interface material (TIM), and/or solid phase thermal interface material (TIM).

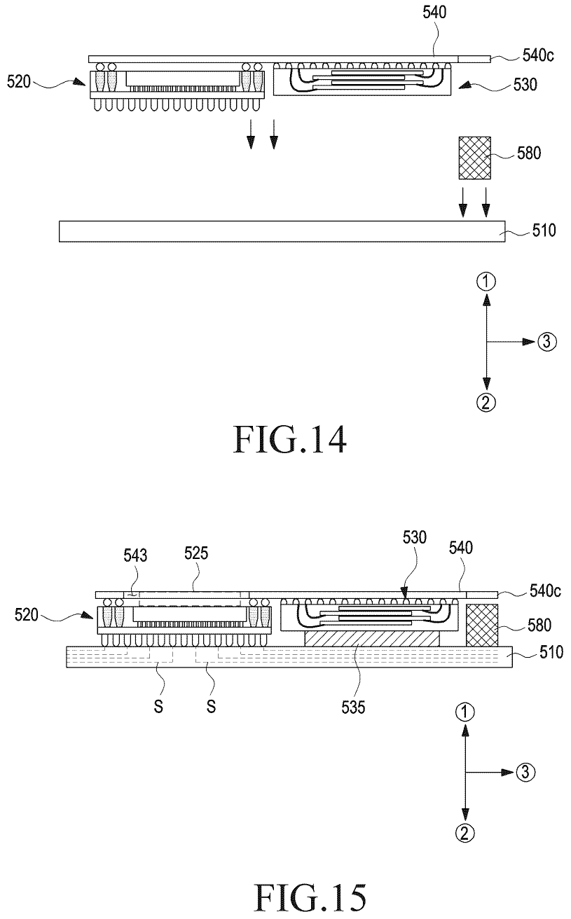

FIG. 14 is a diagram illustrating an example configuration in which the electronic components, the second circuit board, and the spacer that are coupled in FIG. 6 are coupled to the first circuit board according to an embodiment. FIG. 15 is a diagram illustrating a semiconductor package heat dissipation structure that further includes a spacer according to an embodiment.

According to an embodiment, during the assembly process of the semiconductor package heat dissipation structure, an intermediate assembly including the second circuit board 540 and the electronic components (e.g., the first electronic component 520 or the second electronic component 530) may become tilted in relation to the first circuit board 510 due to errors in the product or manufacturing process. In an embodiment, as the intermediate assembly tilts, some components may make contact with the first circuit board 510 and may become damaged. For example, cracks or cold soldering phenomena may occur in the plurality of (1-1) th pins 521 or soldering portions of the first electronic component 520 due to temperature and humidity at a certain location (e.g., P1), or shorts may occur due to damage to the plurality of (1-1) th pins 521 or the soldering area at a certain position (e.g., P2). In this way, when cold soldering phenomena or shorts occur, the intermediate assembly may be tilted. When the intermediate assembly is tilted, the second electronic component 530 may collide with the first circuit board 510 at a certain position (e.g., P3) and may be damaged.

Accordingly, according to an embodiment of the disclosure, a semiconductor package heat dissipation structure that further includes a spacer 580 may be applied. The spacer 580 is attached to the first circuit board 510 or the second circuit board 540, which may prevent and/or reduce titling of an intermediate assembly that includes the electronic components (e.g., the first electronic component 520 or the second electronic component 530) and the second circuit board 540 with respect to the first circuit board 510.

Referring to FIGS. 14 and 15, the spacer 580 may be disposed to be spaced apart by a predetermined distance from one end 540c of the second circuit board 540, taking into account design tolerances. For example, the distance between the spacer 580 and the second circuit board 540 may be smaller than the distance between the second electronic component 530 and the first circuit board 510.

The embodiment illustrated in FIGS. 14 and 15 is an example of a semiconductor package heat dissipation structure that further includes a spacer 580, and various other embodiments may also be implemented. For instance, while the spacer 580 is shown as being disposed adjacent to the second electronic component 530 in FIGS. 14 and 15, it may alternatively or additionally be disposed adjacent to the first electronic component 520. Alternatively, when the second circuit board 540 has a rectangular shape when viewed from above (e.g., in the second direction), the spacer 580 may be disposed at positions corresponding to the four corners of the second circuit board 540.

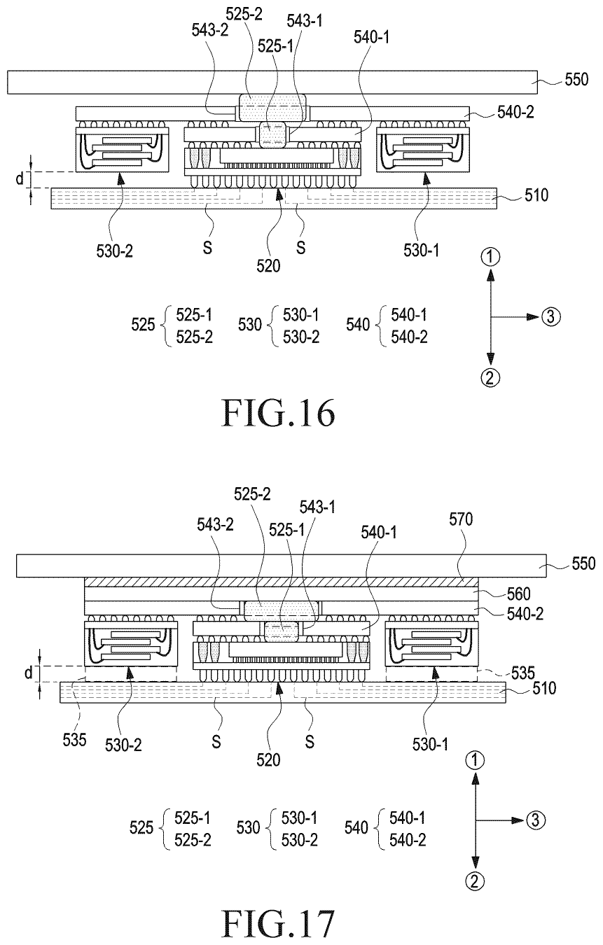

FIG. 16 is a diagram illustrating a semiconductor package heat dissipation structure according to an embodiment.

In the semiconductor package heat dissipation structure according to an embodiment of the disclosure, a multi-layer interposer structure may be formed to compensate for the height difference of electronic components located at substantially different levels (or heights). For example, the first electronic component 520 and the second electronic component 530 may be positioned on substantially different planes, as shown in FIG. 17. When the first electronic component 520 and the second electronic component 530 are arranged within the electronic device, they may have a significant height difference (d). To compensate for this height difference (d), the shape of the second circuit board 540 may be modified. According to an embodiment, the second circuit board 540 may include a (2-1) th printed circuit board 540-1 (may referred as a first second printed circuit board 540-1) on which the first electronic component 520 is disposed and a (2-2) th printed circuit board 540-2 (may referred as a second second printed circuit board 540-2) on which the second electronic component 530 is disposed. In this case, the (2-1) th printed circuit board 540-1 and the (2-2) th printed circuit board 540-2 may be included to be utilized as an interposer to accommodate at least one electronic component (520, and 530), while being located at substantially different interfaces (levels) (or heights). According to an embodiment, the (2-1) th printed circuit board 540-1 and the (2-2) th printed circuit board 540-2 may be formed to be stacked with each other.

According to an embodiment, the second circuit board 540 may accommodate multiple electronic components. For example, referring to FIG. 17, the second electronic component 530 may be divided into a (2-1) th electronic component 530-1 (may referred to as a first second electronic component 530-1) and a (2-2) th electronic component 530-2 (may referred to as a second second electronic component 530-2), which are both included, and may be arranged at different positions on the (2-2) th printed circuit board 540-2 of the second circuit board 540. The first electronic component 520 may be arranged on the (2-1) th printed circuit board 540-1 of the second circuit board 540. As illustrated in FIG. 16, an embodiment that includes printed circuit boards that are separately disposed on different levels (or heights) of the second circuit board 540 may be referred to as “the second circuit board 540 forming a multi-layer interposer structure.”

According to an embodiment, when the second circuit board 540 forms a multi-layer interposer structure, the openings may also be included at multiple layers. For example, as illustrated in FIG. 16, the (2-1) th printed circuit board 540-1 may include a (1-1) th opening 543-1 (may referred as a first first opening 543-1), and the (2-2) th printed circuit board 540-2 may include a (1-2) th opening 543-2 (may referred as a second first opening 543-2). The (1-1) th opening 543-1 and the (1-2) th opening 543-2 may include first thermal interface materials 525-1 and 525-2, respectively, which are disposed at different levels (or heights) to dissipate heat generated from the first electronic component 520. According to an embodiment illustrated in FIG. 17, the first thermal interface materials 525-1 and 525-2 may be disposed adjacent to each other. According to an embodiment, the heat generated from the first electronic component 520 may be sequentially transferred through the first TIM 525-1 and another first TIM 525-2 to the heat dissipation device 550.

FIG. 17 is a diagram illustrating a semiconductor package heat dissipation structure that further includes a heat dissipation plate and a third TIM, according to the embodiment.

Even when the second circuit board 540 forms a multilayer interposer structure, a heat dissipation plate 560 and a third TIM 570 may be applied. For example, as shown in FIG. 17, when the second circuit board 540 includes a (2-1) th printed circuit board 540-1 and a (2-2) th printed circuit board 540-2 stacked on the (2-1) th printed circuit board 540-1, the heat dissipation plate 560 and the third TIM 570 are attached on the (2-2) th printed circuit board 540-2 to more efficiently distribute heat.

According to an embodiment, a gap (d) between the second electronic component 530 and the first circuit board 510 may be filled by electronic components disposed between the second electronic component 530 and the first circuit board 510, supporting members (e.g., the first support member 332 (e.g., bracket) of FIG. 3, the second support member 360 (e.g., rear case)), the printed circuit boards 510 and 540, and/or the housing (e.g., housing 310 of FIG. 3). Alternatively, according to an embodiment, as shown FIG. 17, the gap (d) between the second electronic component 530 and the first circuit board 510 may also be filled by the second TIM 535.

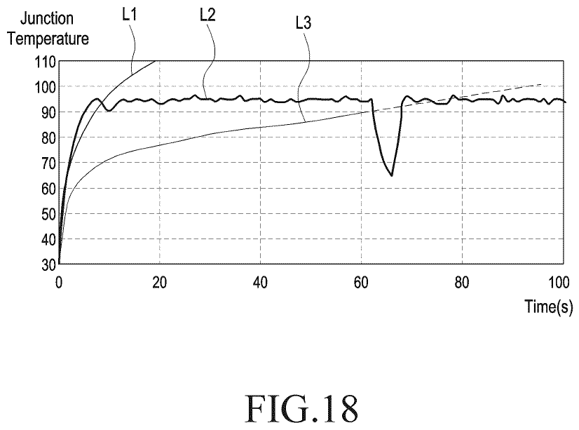

FIG. 18 is a graph showing junction temperature according to an embodiment.

FIG. 18 is a graph showing the junction temperature of electronic devices according to various embodiments. The term junction here may refer to an arbitrary measurement point that includes an intersection between components of the electronic device, or an intersection between a component and a structure.

According to an embodiment, the first graph (L1) in FIG. 18 shows the change in junction temperature over time based on simulation results for a package-on-package (POP) structure, the second graph (L2) may represents the change in junction temperature over time based on actual measurements for a package-on-package (POP) structure, and the third graph (L3) may represent the change in junction temperature over time based on simulation results for the semiconductor package heat dissipation structure in the disclosure herein.

Referring to FIG. 18, according to the semiconductor package heat dissipation structure of the disclosure, it may be seen that the change in junction temperature is more gradual compared to the simulation and actual measurement results for the package-on-package (POP) structure. For example, the semiconductor package heat dissipation structure may improve the junction temperature by approximately 20 degrees compared to the POP structure. Additionally, it may be seen that the time to reach the critical temperature (approximately 90 degrees) takes 80 seconds for the semiconductor package heat dissipation structure, whereas it takes 10 seconds for the simulation results.

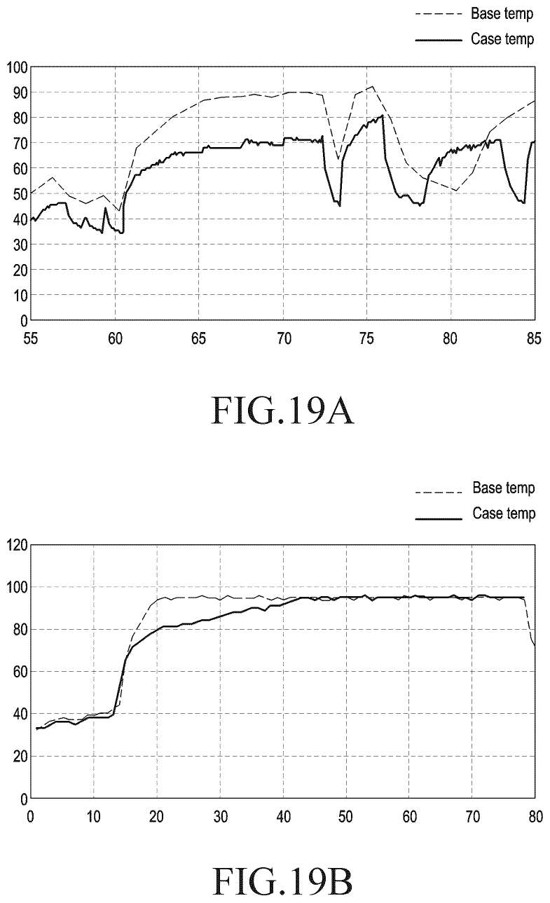

FIG. 19A is a graph showing the peak performance of an electronic component according to an embodiment. FIG. 19B is a graph showing the peak performance of an electronic component, according to an embodiment.

Referring to FIG. 19A and FIG. 19B, it may be seen that the peak performance with respect to different electronic components is improved according to the temperature difference inside the chip with the application of the semiconductor package heat dissipation structure of the disclosure. For example, FIG. 19A illustrates the change in peak performance (vertical axis) according to the change in internal temperature (horizontal axis) of the CPU, and FIG. 19B illustrates the change in peak performance (vertical axis) according to the change in internal temperature (horizontal axis) of the GPU.

For example, FIG. 19A shows that the peak performance of a CPU with the semiconductor package heat dissipation structure of the disclosure applied is improved by approximately 6% or more compared to the base structure in the range of approximately 60 to 75 degrees. Similarly, FIG. 19B shows that the peak performance of a GPU with the semiconductor package heat dissipation structure of the disclosure applied is improved by approximately 7% or more compared to the base structure in the range of approximately 60 to 75 degrees.

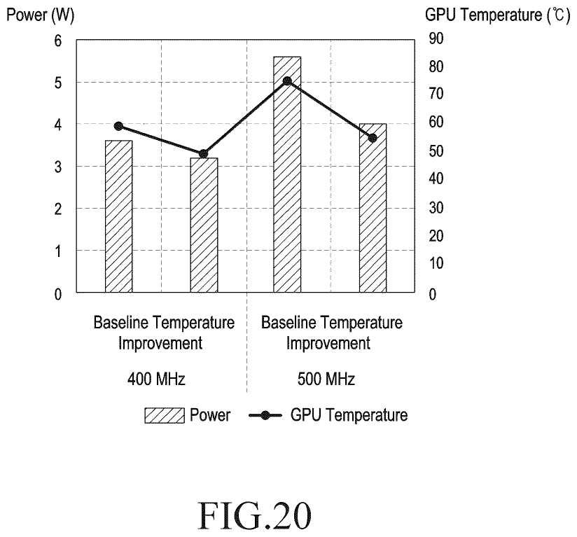

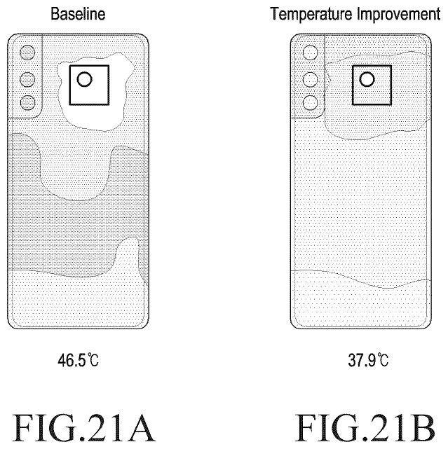

FIG. 20 is a graph showing the power and temperature of an electronic component according to an embodiment. FIG. 21A is a diagram illustrating the surface temperature of an electronic device according to an embodiment. FIG. 21B is a diagram illustrating the surface temperature of an electronic device according to an embodiment.

FIG. 20 to FIG. 21B may represent performance indicators for the sustainability of the electronic device according to the improvement of heat dissipation performance. FIG. 21A shows that the surface temperature of the electronic device was measured to be 46.5 degrees under an operating environment of 500 MHz, and FIG. 21B shows that the surface temperature of the electronic device was measured to be 39.9 degrees under an operating environment of 500 MHz.

For example, referring to FIG. 20 and FIG. 21B, when the semiconductor package heat dissipation structure of the disclosure is applied to the electronic component, it may be seen that the temperature of the GPU is improved by at least 10 degrees at 400 MHz operating environment and by at least 20 degrees at 500 MHz operating environment with the clock fixed. This improvement is achieved through the reduction of GPU leakage power, resulting in the improvement of the surface temperature of the electronic device. Furthermore, the performance enhancement effect may be used as a reference to increase the frequency of the GPU in the operating environment, for example, from 400 MHz to 500 MHz.

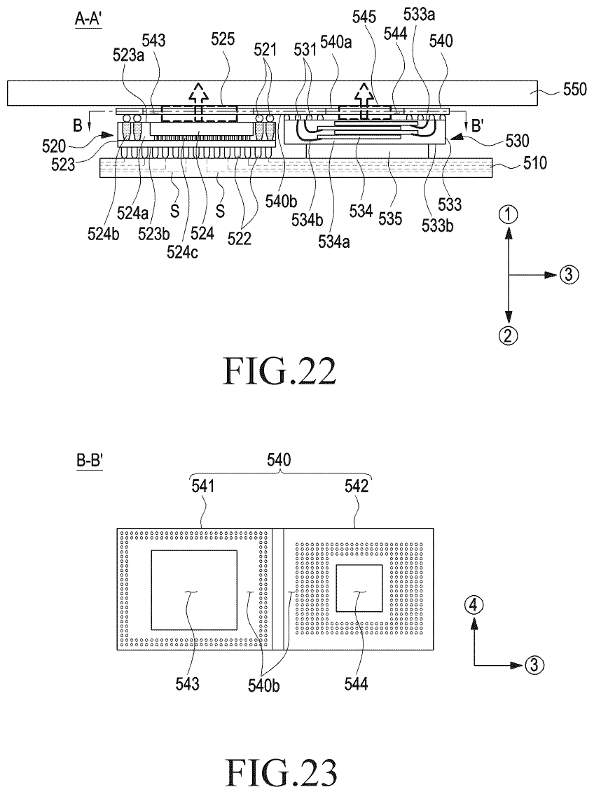

FIG. 22 illustrates a cross-section of the semiconductor package heat dissipation, according to an embodiment. FIG. 23 illustrates a surface of the second circuit board, according to an embodiment. With respect to the embodiments of FIGS. 22 and 23, descriptions of components identical to those mentioned in the embodiments may be omitted within overlapping scopes.

The electronic device (e.g., the electronic device 101 of FIGS. 1 to 3) may serve as the semiconductor package heat dissipation, comprising a heat dissipation device 550, a first TIM 525, and a second TIM 535.

The first TIM 525 and the second TIM 535 may be provided to dissipate heat from the first electronic component 520 and the second electronic component 530, respectively.

Referring to FIG. 22, the electronic device (e.g., the electronic device 101 of FIGS. 1 to 3) may serve as the semiconductor package heat dissipation, including a fourth TIM (thermal interface material) 545. The fourth TIM 545 may be provided to dissipate heat from the second electronic component 530. The fourth TIM 545 may additionally or alternatively be provided for, or in replacement of, at least one of the components including the heat dissipation device 550, the first TIM 525, and the second TIM 535.

Referring to FIG. 22 and FIG. 23 together, the fourth TIM 545 may be placed within the second opening 544 formed in the second area 542 of the second circuit board 540, to transfer heat from the second electronic component 530 to the heat dissipation member 550. According to an embodiment illustrated in FIG. 22 and FIG. 23, the second opening 544 formed in the second area 542 is depicted as having a smaller area compared to the first opening 543 formed in the first area 541, but this is not necessarily limited thereto.

For example, the electronic device (e.g., the electronic device 101 of FIGS. 1 to 3) may enhance heat dissipation performance by including a fourth TIM 545 in addition to the heat dissipation device 550, the first TIM 525, and the second TIM 535. The heat from the second electronic component 530 may be transferred to the first circuit board 510 through the second TIM 535 or may be transferred to the heat dissipation device 550 through the fourth TIM 545.

According to an embodiment, the fourth TIM 545 may include at least one of carbon fiber TIM (thermal interface material), liquid phase TIM (thermal interface material), acrylic TIM (thermal interface material), and/or solid phase TIM (thermal interface material).

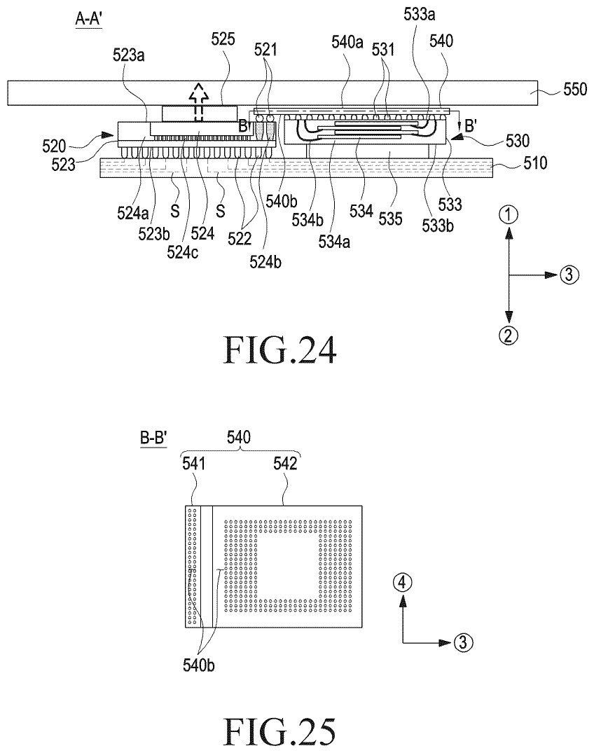

FIG. 24 illustrates a cross-section of the semiconductor package heat dissipation, according to an embodiment. FIG. 25 illustrates a surface of the second circuit board, according to an embodiment. Descriptions of components identical to those mentioned in the aforementioned embodiments may be omitted within overlapping scopes.

The second circuit board 540 may have a shape where it is stacked at least partially with the first circuit board 510 in a state spaced apart by a predetermined distance in the first direction (1). The second circuit board 540 may form a stacked board structure with the first circuit board 510.

Referring to FIG. 24 and FIG. 25, the second circuit board 540 may overlap at least a portion of the first electronic component 520. While the embodiments described focus on an example where the second circuit board 540 has a first opening 543 formed in the first area 541, the scope of the present disclosure is not necessarily limited to embodiments including the first opening 543. As shown in FIG. 24, the second circuit board 540 may also be implemented in a shape overlapping with the first electronic component 520 without an opening.

According to an embodiment, the first electronic component 520 may overlap at least a portion of the first area 541 of the second circuit board 540. The first TIM 525 may be stacked with the heat dissipation device 550 in a state where it does not overlap with the first area 541 of the second circuit board 540, to transfer heat from the first electronic component 520 to the heat dissipation device 550.

The electronic device (e.g., the electronic device 101 of FIGS. 1 to 3) may transmit and receive large amounts of data frequently and rapidly between electronic components (e.g., the first electronic component 520 and/or the second electronic component 530). Therefore, the electronic device (e.g., the electronic device 101 of FIGS. 1 to 3) may include a large number of signal lines (or data lines). As signal loss increases with the lengthening of the data lines, it may be desirable for the electronic components connected via signal lines to be arranged adjacent to each other. However, if the electronic components are arranged in overlapping positions, heat dissipation may not be efficient.

According to the present disclosure, signal lines may be routed on a printed circuit board (e.g., the second circuit board 540) containing two adjacent areas (e.g., the first area 541 and the second area 542). Additionally, electronic components may be arranged in these two adjacent areas to perform heat dissipation. As per the present disclosure, by arranging electronic components in close proximity without overlapping, it is possible to reduce and/or prevent signal loss while maintaining high heat dissipation performance.

An electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software 140 (e.g., the program) including one or more instructions that are stored in a storage medium (e.g., internal memory 136 or external memory 138) that is readable by a machine (e.g., the electronic device). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an example embodiment of the disclosure, an electronic device may comprise: a first circuit board; a second circuit board including a first surface facing a first direction, and a second surface facing a second direction opposite to the first direction and facing the first circuit board; a first electronic component disposed between the first circuit board and the second surface of the second circuit board, and disposed in a first area of the second circuit board; a second electronic component disposed between the first circuit board and the second surface of the second circuit board, and disposed in a second area of the second circuit board; a heat dissipation device comprising a heat conducting material disposed on the first surface of the second circuit board; a first TIM (thermal interface material) comprising a thermally conductive material disposed in an first opening formed in the first area of the second circuit board between the second surface of the second circuit board and the first circuit board and configured to transfer heat from the first electronic component to the heat dissipation device; and a second TIM (thermal interface material) comprising a thermally conductive material disposed between the second electronic component and the first circuit board and configured to transfer heat from the second electronic component to the first circuit board.

According to an example embodiment, the electronic device may further include a heat dissipation plate disposed between the second circuit board and the heat dissipation device.

According to an example embodiment, the electronic device may further include a third TIM (thermal interface material) comprising a thermally conductive material disposed between the heat dissipation plate and the heat dissipation device.

According to an example embodiment, the first TIM or the second TIM may include at least one of carbon fiber thermal interface material (TIM), liquid phase thermal interface material (TIM), acrylic thermal interface material (TIM), and/or solid phase thermal interface material (TIM).

According to an example embodiment, the first electronic component and the second electronic component are positioned on substantially the same plane on the second circuit board.

According to an example embodiment, the first electronic component may include a first case, a first chip located in the first case, and a plurality of first first pins and a plurality of second first (pins for electrical connection with the first chip and other components, and the second electronic component may include a second case, a second chip located in the second case, and a plurality of second pins for electrical connection with the second chip and other components.

According to an example embodiment, the first electronic component is connected to the first circuit board through the plurality of (1-2) th pins and is connected to the second circuit board through the plurality of (1-1) th pins, and the second electronic component is connected to the second circuit board through the plurality of second pins.

According to an example embodiment, the first chip may be electrically connected to the first circuit board using solder balls, and solder balls may be formed on a surface of the first chip in a direction toward the second surface of the first case facing in the first circuit board.

According to an example embodiment, the second chip may be electrically connected to the second circuit board using a wire, and the wire may be wired from the second chip to the first surface of the second case facing in the second circuit board.

According to an example embodiment, the first electronic component is configured with a (1-1) th pins formed from the first case toward the second circuit board to surround the first opening.

According to an example embodiment, the electronic device may further include a spacer disposed between the first circuit board and the second circuit board to prevent and/or reduce tilting of the second circuit board.

According to an example embodiment, the spacer may be disposed on the first circuit board and may be formed to be spaced apart by a specified distance from at least one end of the second circuit board.

According to an example embodiment, the second circuit board may include a (2-1) th circuit board on which the first electronic component is disposed, and a (2-2) th circuit board on which the second electronic component is disposed.

According to an example embodiment, the (2-1) th circuit board may include a (1-1) th opening; the (2-2) th circuit board may include a (1-2) th opening; and the (1-1) th opening and the (1-2) th opening are configured to at least partially overlap each other.

According to an example embodiment, the (2-1) th circuit board may be disposed between the (2-2) th circuit board and the first circuit board.

According to an example embodiment, the first electronic component may be positioned on a substantially different plane from the second electronic component.

According to an example embodiment of the disclosure, an electronic device may comprise a first circuit board; a second circuit board including a first surface facing a first direction and a second surface facing a second direction opposite to the first direction; a first electronic component including a plurality of (1-2) th pins disposed in a first area of the second circuit board for electrical connection with other components, the first electronic component being an electronic component disposed between the first circuit board and the second circuit board; a second electronic component including a plurality of second pins disposed in a second area of the second circuit board for electrical connection with other components; and a heat dissipation device comprising a thermally conductive material disposed on the first surface of the second circuit board, wherein the first electronic component is connected to the first circuit board through the plurality of (1-2) th pins, and the second electronic component is connected the second circuit board through the plurality of second pins. When the first electronic component and the second electronic component are disposed on the second circuit board, the plurality of (1-2) th pins of the first electronic component, and the plurality of second pins of the second electronic component are formed to face in opposite directions.

According to an example embodiment, the electronic device may further include a first TIM comprising a thermally conductive material disposed in an first opening formed in the first area of the second circuit board and configured to transfer heat from the first electronic component to the heat dissipation device; and a second TIM comprising a thermally conductive material disposed between the second electronic component and the first circuit board and configured to transfer heat from the second electronic component to the first circuit board.

According to an example embodiment, the electronic device may further include a heat dissipation plate disposed between the second circuit board and the heat dissipation device.

According to an example embodiment, the electronic device may further include a third TIM comprising a thermally conductive material disposed between the heat dissipation plate and the heat dissipation device.

According to an example embodiment, the electronic device may further include a spacer disposed between the first circuit board and the second circuit board.

According to an embodiment, the first electronic component may include a first circuit board having a first area corresponding to a first electronic component and a second area, non-overlapped with the first area, corresponding to a second electronic component 530 a second circuit board including a first surface facing a first direction, a second surface facing a second direction opposite to the first direction and facing the first circuit board; and a heat dissipation device disposed above the first surface of the second circuit board, the heat dissipation device connected with the first electronic component via a first TIM (thermal interface material). The first electronic component is electrically connected with the first circuit board and second circuit board, and is disposed between the first circuit board and at least portion of the second circuit board. The second electronic component is electrically connected with the second circuit board and, is disposed between the first circuit board and at least portion of second circuit board, such that the first electronic component and the second electronic component are electrically connected through the second circuit board.

According to an embodiment, the electronic device may further include a second TIM disposed between the second electronic component and the first circuit board and configured to transfer heat from the second electronic component to the first circuit board 510.

According to an embodiment, the second circuit board may include a first opening corresponding to the first electronic component, the heat dissipation device connected with the first electronic component via the first TIM through the first opening.

According to an embodiment, the second circuit board may include a second opening 544 corresponding to the second electronic component, the heat dissipation device connected with the second electronic component via the first TIM through the second opening.

According to an embodiment, the first electronic component may be connected with the first circuit board via a 1-2 th pin, and is connected with the second circuit board via a 1-1 th pin.

According to an embodiment, the second electronic component may be connected with the second circuit board via a second pin.

According to an embodiment, the heat dissipation device may be directly disposed on the first surface of the second circuit board.

According to an embodiment, the heat dissipation device may be disposed on the first surface of the second circuit board via a third TIM.

According to an embodiment, the first electronic component may include at least one of an application processor and a communication processor, and the second electronic component may include memory.

According to an embodiment, the first electronic component and the second electronic component may be disposed adjacent each other.

Although the disclosure has been described in detail with respect to various example embodiments, it will be apparent to those skilled in the art that various modifications and changes may be made without departing from the scope of the present disclosure. Such modifications and changes are intended to be covered by the appended claims and their equivalents, and are within the scope of the disclosure as described herein, including the entirety of the disclosure and its equivalents, without departing from the spirit of the present disclosure understood by those skilled in the art. It will also be understood that any of the embodiment(s) described herein may be used in conjunction with any other embodiment(s)

What is claimed is:

1. An electronic device, comprising:
a first circuit board having a first area corresponding to a first electronic component and a second area, non-overlapped with the first area, corresponding to a second electronic component;
a second circuit board including a first surface facing a first direction, a second surface facing a second direction opposite to the first direction and facing the first circuit board; and
a heat dissipation device disposed above the first surface of the second circuit board, the heat dissipation device connected with the first electronic component via a first TIM (thermal interface material);
wherein the first electronic component is electrically connected with the first circuit board and second circuit board, and is disposed between the first circuit board and at least portion of the second circuit board;
wherein the second electronic component is electrically connected with the second circuit board and, is disposed between the first circuit board and at least portion of second circuit board, such that the first electronic component and the second electronic component are electrically connected through the second circuit board.

2. The electronic device of claim 1, comprising:
a second TIM disposed between the second electronic component and the first circuit board and configured to transfer heat from the second electronic component to the first circuit board.

3. The electronic device of claim 1,
wherein the second circuit board includes a first opening corresponding to the first electronic component, the heat dissipation device connected with the first electronic component via the first TIM through the first opening.

4. The electronic device of claim 1,
wherein the second circuit board includes a second opening corresponding to the second electronic component, the heat dissipation device connected with the second electronic component via the first TIM through the second opening.

5. The electronic device of claim 1, wherein the first electronic component is connected with the first circuit board via a second first pin, and is connected with the second circuit board via a first first pin.

6. The electronic device of claim 1, wherein the second electronic component is connected with the second circuit board via a second pin.

7. The electronic device of claim 1, wherein the heat dissipation device is directly disposed on the first surface of the second circuit board.

8. The electronic device of claim 1, wherein the heat dissipation device is disposed on the first surface of the second circuit board via a third TIM.

9. The electronic device of claim 1, wherein the first electronic component includes at least one of an application processor and a communication processor, and
wherein the second electronic component includes memory.

10. The electronic device of claim 1, wherein the first electronic component and the second electronic component are disposed adjacent each other.

11. The electronic device of claim 1, further comprising:
a heat dissipation plate disposed between the second circuit board and the heat dissipation device.

12. The electronic device of claim 1, wherein the first electronic component and the second electronic component are formed to face opposite directions when assembled on the second circuit board, based on the electrical connection directions of a first chip embedded in the first electronic component and a second chip embedded in the second electronic component.

13. The electronic device of claim 1, further comprising a spacer disposed between the first circuit board and the second circuit board and configured to prevent tilting of the second circuit board.

14. The electronic device of claim 1, wherein the second circuit board comprises a first second circuit board on which the first electronic component is disposed, and a second second printed circuit board on which the second electronic component is disposed.

15. The electronic device of claim 14, wherein:
the first second circuit board comprises a first first opening;
the second second circuit board comprises a second first opening; and
the first opening and the second opening are at least partially overlap each other.

16. An electronic device, comprising:
a first circuit board;
a second circuit board including a first surface facing a first direction and a second surface facing a second direction opposite to the first direction;
a first electronic component including a plurality of second first pins disposed in a first area of the second circuit board for electrical connection with other components, the first electronic component including an electronic component disposed between the first circuit board and the second circuit board,
a second electronic component including a plurality of second pins disposed in a second area of the second circuit board for electrical connection with other components; and
a heat dissipation device comprising a thermally conductive material disposed on the first surface of the second circuit board,
wherein the first electronic component is connected to the first circuit board through the plurality of second first pins, and the second electronic component is connected the second circuit board through the plurality of second pins,
wherein when the first electronic component and the second electronic component are disposed on the second circuit board, the plurality of second first pins of the first electronic component, and the plurality of second pins of the second electronic component are formed to face in opposite directions.

17. The electronic device of claim 16, further comprising a first heat transfer member comprising a thermally conductive material disposed in an opening formed in the first area of the second circuit board and configured to transfer heat from the first electronic component to the heat dissipation device; and a second heat transfer member comprising a thermally conductive material disposed between the second electronic component and the first circuit board and configured to transfer heat from the second electronic component to the first circuit board.

18. The electronic device of claim 16, further comprising a heat dissipation plate disposed between the second circuit board and the heat dissipation device.

19. The electronic device of claim 16, further comprising a third heat transfer member comprising a thermally conductive material disposed between the heat dissipation plate and the heat dissipation device.

20. The electronic device of claim 16, further comprising a spacer disposed between the first circuit board and the second circuit board.
